(19) United States
(12) Patent Application Publication
(10) Pub. No.: US 2026/0228147 A1
(43) Pub. Date: Aug. 6, 2026

(54) DIE-TO-DIE BYPASS MODE FOR CHIPLET INITIALIZATION, CONFIGURATION, AND COMMUNICATION

(71) Applicant: Microsoft Technology Licensing, LLC, Redmond, WA (US)

(72) Inventors: Charles Walter BOECKER, Ames, IA (US); Michael Raymond TROMBLEY, Cary, NC (US); Eric Douglas GROEN, Ankeny, IA (US); Terrence Huat Hin TAN, Bayan Lepas (MY); Simon Shichi LI, Cupertino, CA (US); Roxanne VU, San Jose, CA (US); Pradipta Kumar GHOSH, Palo Alto, CA (US); Ravi SHIVNARAINE, Pickering (CA)

(21) Appl. No.: 19/044,051

(22) Filed: Feb. 3, 2025

(51) Int. Cl. G06F 13/36

(52) U.S. Cl. CPC G06F 13/36; G06F 2213/40

(57) ABSTRACT

The described technology provides a device including. a transmitter configured on a transmitting die, a receiver configured on a receiving die, an interposer configured to communicate between the transmitting die and the receiving die at a test frequency that is equal or lower than the normal operating frequency of the system on a system on chip (SoC), and a plurality of pins configured on each of the transmitting die and the receiving die, wherein the plurality of pins are configured to communicate with the interposer at the test frequency.

### BACKGROUND

System on chip (SoC) may be implemented as an integrated circuit (IC) design that combines many or all high-level function elements of an electronic device onto a single chip instead of using separate components mounted to a motherboard, as is done in traditional electronics design. Modern electronic and computing systems use logic configured SoC architecture generally include a number of dies or chiplets. Before SoC are delivered and deployed in electronic devices a number of calibration methods are used to ensure proper functioning of the SoC.

### SUMMARY

The described technology provides a device including. a transmitter configured on a transmitting die, a receiver configured on a receiving die, an interposer configured to communicate between the transmitting die and the receiving die at a test frequency that is equal or lower than the normal operating frequency of the system on a system on chip (SoC), and a plurality of pins configured on each of the transmitting die and the receiving die, wherein the plurality of pins are configured to communicate with the interposer at the test frequency.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Other implementations are also described and recited herein.

### BRIEF DESCRIPTIONS OF THE DRAWINGS

The disclosure will be readily understood by the following detailed description in conjunction with the accompanying drawings, wherein like reference numerals designate like structural elements.

It should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

FIG. 1 illustrates an example implementation of a D2D communication system for die initialization, configuration, and communication of design for test vectors.

FIG. 2 illustrates an example implementation of interposer routes for communication between dies to provide redundancy.

FIG. 3 illustrates a more detailed implementation of an example die-to-die (D2D) communication system using transmitter and receiver electrically connected via an interposer.

FIG. 4 illustrates an example implementation of the D2D communication system disclosed herein.

### DETAILED DESCRIPTIONS

System on chip (SoC) may be implemented as an integrated circuit (IC) design that combines many or all high-level function elements of an electronic device onto a single chip instead of using separate components mounted to a motherboard, as is done in traditional electronics design. Modern electronic and computing systems use logic configured SoC architecture generally include a number of dies or chiplets. Before SoC are delivered and deployed in electronic devices a number of calibration methods are used to ensure proper functioning of the SoC. To ensure proper functioning of the SoC, not only the dies need to be calibrated, but die-to-die communication also needs to be calibrated.

Implementations disclosed herein disclose a system for providing reliable communication between two dies (or chiplets) before fusing any of the on-die connectors. Specifically, one or more implementations disclosed herein disclosed herein provides SoC configuration where die-to-die (D2D) pins are re-purposed so that the pins can be used as low frequency bus before calibration of the SoC is completed. In one implementation, the technology disclosed herein provides for collecting low-frequency communication between two chiplets using n over m test and uses it to determine which combination of chiplets are defect free.

Implementations disclosed herein provide an interposer configured to communicate between two dies. For example, the interposed may communicate between a transmitting die including a transmitter and a receiving die with a receiver. Each of the transmitting and the receiving dies may include a number of D2D communication pins that are reconfigured to be used as low frequency bus. For example, the D2D pins are configured to communicate at a lower test frequency compared to the frequency of operation of the SoC during its normal operation in the field. In one implementation, the D2D communication pins are reconfigured to communicate at one-twentieth ( 1/20^{th}) to one-tenth ( 1/10^{th}) of the frequency of operation of the SoC during its normal operation in the field. For example, the D2D pins are reconfigured to communicate at test-frequency of 400 MHz or less for an SoC that has a normal operational frequency of 20 GHz.

The interposer may include a number of interposer routes that are communicatively connected between the reconfigured D2D pins of the two dies. In one implementation, the interposer routes also communicate at the test frequency between the dies. The implementation of the reconfigured D2D communication pins and the interposer routes may be used as a low-frequency route between the dies before calibration of the SoC is completed. Specifically, this configuration allows for setting up the configuration of the dies before bring-up a chiplet (die) based SoC design into production. Furthermore, this low-frequency implementation may also be used to start initialization of the D2D communication and for passing a design for test (DFT) vector to mark bad parts on the SoC after the assembly.

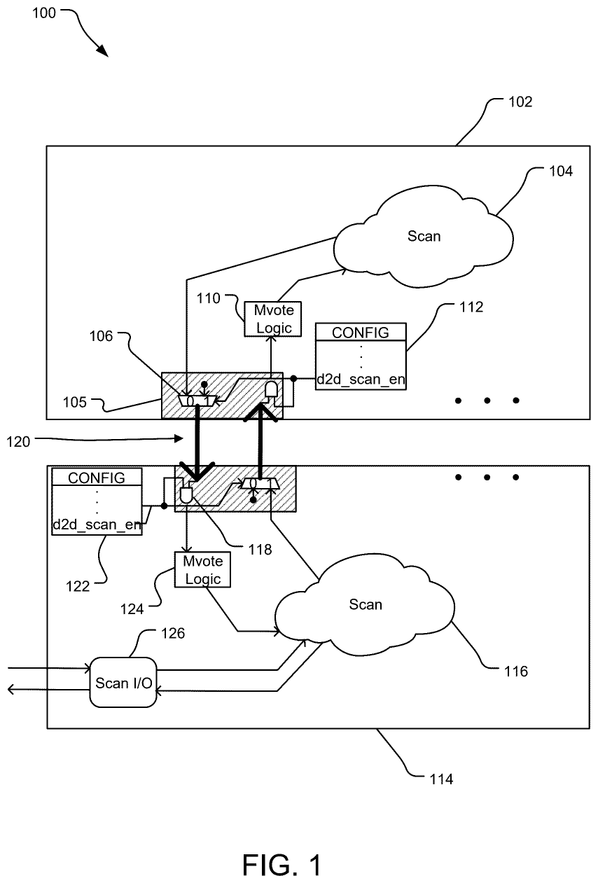

FIG. 1 illustrates an implementation of a D2D communication system 100 for die initialization, configuration, and communication of design for test vectors. Specifically, the D2D communication system 100 allows providing automatic test pattern generation (ATPG) scan support between two dies 102 and 114. Specifically, the die-to-die communication system 100 allows scan support to determine yield of the SoC on which various dies, such as the dies 102 or 104 are configured, to sort the dies before undertaking any fusing of the dies. Here the yield may indicate how many of the dies have communication links that are free from manufacturing defects so that these dies can be used on the SoC.

For example, the yield may be measured in terms of percentages of the usable parts to the total parts that can be determined using the D2D communication system 100. The D2D communication system 100 provides robust communication between the dies 102 or 104, in a low-frequency mode, before any lane repair. For example, each die contains a physical layer (PHY), 105. The PHY contains a transmitter TX 106 and a receiver RX 118. The traffic flow can be in either direction from die 102 to die 114 and/or die 114 to 102. For example, the die 102 (referred to as the transmitting die 102) may include a transmitter Tx 106 and the die 104 (referred to as the receiving die 114) may include a receiver Rx 118. In one implementation, the transmitting die 102 and the receiving die 114 are configured to be connected using a link macro, wherein the connections between the dies are double-bumped. Furthermore, in one implementation, the data communicated over the link macro is single bumped. In one implementation, there may be two types of connections between the dies. A clock connection and a data connection. The clock connection may be double bumped to protect against yield fall out from assembly. On the other hand, the data connection may be single bumped. The majority vote logic is added to protect against yield fall out from assembly on the data connections.

The transmitter Tx 106 may communicate with the receiver Rx 118 via an interposer 120 that is configured to communicate between the transmitting die 102 and the receiving die 114 at a test frequency that is at most one tenth of the normal operating frequency of the system on chip (SoC) on which the dies 102 and 114 are configured. The transmitting die 102 may include scan logic 104 and the receiving die 114 may include scan logic 116, each of which may be loaded via a scan I/O 126. Furthermore, the Tx 106 and the Rx 118 may be configured by using configuration files 112 and 122.

In one implementation of the die-to-die communication system 100, one input logic bit from the transmitting die 102 may be communicated as n physical bits over n interposer routes 120 to the receiving die 114, wherein n being greater than one. Majority vote logics 110 and 124 configured on the transmitting die 102 and the receiving die 114 may decode the n physical bits received over the n interposer routes 120 to convert the n physical bits to one output logic bit.

For example, in one implementation, the ATPG scan support may be achieved by a 3-bit majority vote for data, with 3 physical bits received over the 3 interposer routes 120 for each input logic bit from the transmitting die 102. In this implementation, clock signals between the dies 102, 104 may be used without majority to support one clock or data per link macro of the interposer 120. Specifically, the clock signals are double bumped to ensure survivability during assembly. While in this implementation, 3physical bits are used for communicating each logical bit, in an alternative implementation, communicated between the transmitting die and the receiving die includes redundancy such that n interposer routes are used to communicate m physical bits, wherein n is greater than m. For example, n may be 3 and m may be 1. Alternatively, n may be 6 and n may be 2.

Alternatively, a Hamming (7, 4) error-correcting code logic that encodes four bits of data into seven bits by adding three parity bits may also be used. This may require logic on both the transmitting die 102 and the receiving die 114. Using Hamming (7, 4) error-correcting code logic gives an ability to communicate between the transmitting die 102 and the receiving die 114 even when there are one bad lanes out of seven for the transposer 120, thus giving high redundancy for two bad lanes of 14 data lanes of the transposer 120. The implementation using Hamming error correction code logic may provide more efficient use of the routes. For example, hamming (7,4) gives 4/7 of payload. Four logical bits of data for seven physical connections. Majority vote gives ⅓ of payload. One logical bit for three physical connections.

While the above discussion of the die-to-die communication system 100 illustrates a use case for ATPG scan support, the die-to-die communication system 100 can also be used in providing support for other usage cases. Furthermore, the interposer 120 may also be used as a configuration bus for communicating configuration file(s) between the dies 102 and 114 at the test frequency. Such configuration files may be used to bootstrap the dies 102, 114 before die-to-die initialization and calibration.

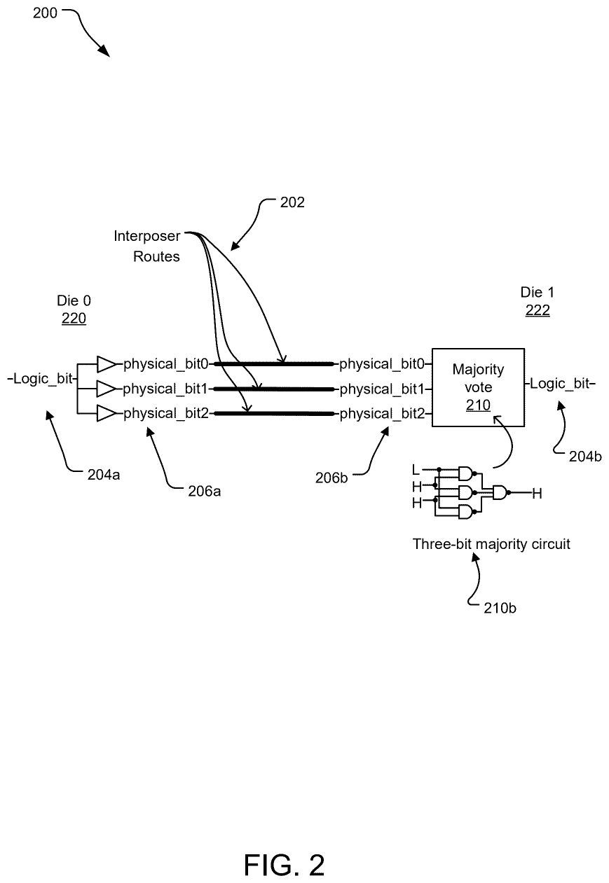

FIG. 2 illustrates an implementation 200 of interposer routes for communication between dies to provide redundancy. Specifically, the implementation 200 of the interposer routes 202 can survive any one of the interposer routes 202 being shorted or open and still be able to achieve communication between two dies. Here a logic bit 204a on a die 0 220 may be converted by a logic on the die 0 220 into three physical bits 206a. In an alternative implementation, m logic bits may be converted to n physical bits to be communicated over n interposer routes, wherein n is greater than m.

The three physical bits 206a are communicated over the interposer routes 202 to a receiving die, die 1 222. A majority logic 210 on the receiving die 1 222 receives the three physical bits 206b and converts them into a logic bit 204b. Specifically, in one implementation the majority logic 210 may be implemented as illustrated by a majority logic circuit 210b. While the interposer routes 202 may be running communication at 20 or more GB/sec in normal operation and sending a lot of data from die 0 220 to die 1 222 using a parallel data path (not shown here). However, the illustrated implementation overrides the parallel data path to communicate at substantially lower frequency between die 0 220 and die 1 222.

In this implementation, even if one of the three interposer routes 202 has an open or shorted connection, the majority logic 210 is still able to recover the correct value of the logic bit 204a, thus providing robust or reliable communication between die 0 220 and die 1 222. However, if two of the three interposer routes 202 have an open or shorted connection, the majority logic 210 is not able to recover the correct value of the logic bit 204a. In this case, the SoC with the dies 220 and 222 may need to be thrown away.

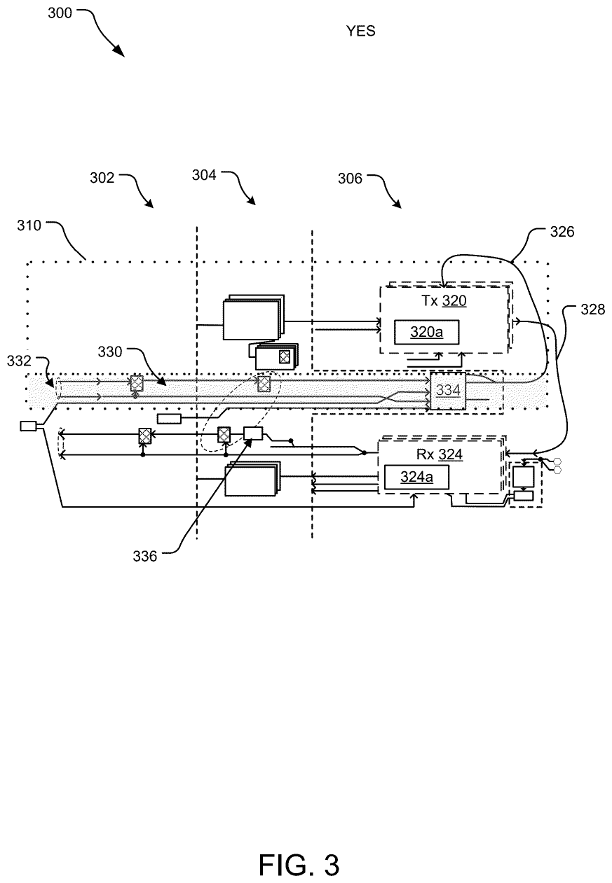

FIG. 3 illustrates a more detailed implementation of die-to-die (D2D) communication system 300 using transmitter and receiver electrically connected via an interposer. Specifically, the top part of the D2D communication system 300 disclosed a high-speed data path 320 during a normal operation of the dies. The D2D communication system 300 may include a D2D soft IP section 302, a D2D hard macro section 304, and a D2D analog section 306.

As illustrated, a transmit line 328 may electrically connect the Tx 320 to the Rx 324 via an interposer. During normal operation, the high-speed data path 320 may operate at high speed, such as in excess of 20 GB/sec. However, in the illustrated implementation, a Tx bypass multiplexer 320a pushes lower frequency data from a low frequency data path 330 (shown shaded) through an on-die route 326 connected to the Tx 320. The low frequency data path 330 may receive a design for test (DFT) vector input 332 from a scan fabric. In one implementation, the DFT vector input may be retimed though the low frequency data path 330 to ensure that the input via the on-die route 326 to the Tx 320 meets the timing requirement. A logic 334 launches the DFT vector input 332 via the on-die route 326 to the Tx 320. In one implementation, the low frequency data path 330 may also forward a clock signal along with the DFT vector input 332.

When input into the Tx 320, the Tx bypass multiplexer 320a pushes the DFT vector input 332 into an Tx-Rx interposer link 328 that communicates it to the Rx 324. In the illustrated implementation, a transmitter (Tx) 320 and a receiver (Rx) 324 are disclosed to be on the same die. However, in majority of implementations, the Tx 320 and the Rx 324 may be configured on different dies. The clock signal forwarded by the low frequency data path 330 may be forwarded along with the DFT vector input 332 into the Rx 324. The Rx 324 may include an Rx bypass multiplexer 324a that forwards the data received from the Tx-Rx interposer link 328 onto a majority vote logic 336.

Thus, as an example, four logical bits of DFT vector input 332 sent on the low frequency data path 330 gets converted into twelve physical bits by the logic 334, thus providing redundancy of three physical bits per each logic bit. These twelve bits are communicated over twelve lane interposer route 326 and are communicated over to twelve independent connections of the Tx-Rx interposer link 328 to the Rx 324. Once the Rx bypass multiplexer 324a forwards the twelve physical bits to the majority vote logic 336, it can recover four logic bits of the DFT vector input 332 from the twelve physical bits. As a result, the implementation of the D2D communication system 300 allows using the bypass Tx multiplexer 320a of the Tx 320 and the bypass Rx multiplexer 324a of the Rx 324 to load the DFT vector data 332 at low frequency on the interposer between two dies.

The D2D communication system 300 between two dies may be extended to multiple dies on a SoC to ascertain the yield of multiple dies on the SoC. Thus, the test infrastructure between two dies, as disclosed herein, may be extended to determine manufacturing defects between and within multiple dies on the SoC. As a result, the D2D communication system 300 allows determining which combination of dies are defect free and to subsequently extend the scan chain across the multiple dies. As a result, scan chains can be routed between multiple dies without having to provide for specific sets of dedicated input/outputs between the dies to route the scan chains between the dies. This enables a way of testing the die within and SoC without dedicated bumps. The function is multiplexed with a function that already exists to communicated between die during normal operation.

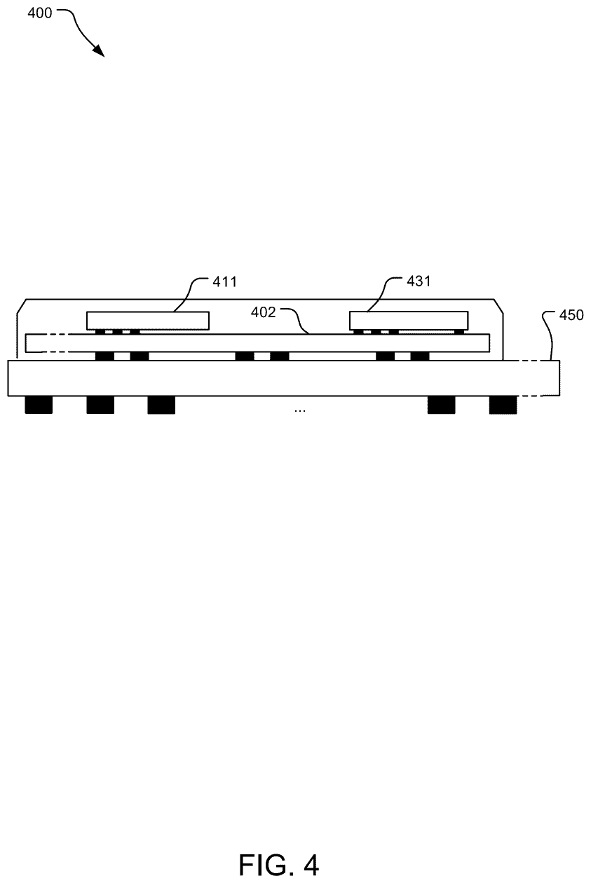

FIG. 4 illustrates an alternative implementation of the D2D communication system 400 disclosed herein. Specifically, the D2D communication system 400 includes a first die 411 and a second die 431 on an SoC 450 that are configured to communicate with each other using an interposer 402. The technology disclosed herein allows determining the silicon yield of the dies 411, 431 before repairing any open or shorts that happened during assembly. Specifically, even if there are bad routes in the interposer 402, the technology disclosed herein allows determining the yield between the two dies, thus surviving the defects in the interposer as it uses redundant interposer links to enable a robust communication between die within the SoC, 450. This enables the testing of die yield before repairing the die-to-die communication, 431. Subsequent tests may be used to determine the faults in the interposer 402.

A device disclosed herein includes a transmitting die including a transmitter, a receiving die including a receiver, wherein the transmitting die and the receiving die are configured to be used on a system on chip (SoC), an interposer configured to communicate between the transmitting die and the receiving die at a test frequency that is equal or lower than the normal operating frequency of the system on chip (SoC). For example, in one implementation, the test frequency is of the order of 400 MHz of less, wherein the normal operating frequency may be of the order of 20 GHz.

A die-to-die communication system disclosed herein includes a transmitter configured on a transmitting die, a receiver configured on a receiving die, an interposer configured to communicate between the transmitting die and the receiving die at a test frequency that is equal or lower than the normal operating frequency of the system on a system on chip (SoC), and a plurality of pins configured on each of the transmitting die and the receiving die, wherein the plurality of pins are configured to communicate with the interposer at the test frequency.

A system on chip disclosed herein includes a transmitting die, a receiving die, an interposer configured to communicate between the transmitting die and the receiving die at a test frequency that is equal or lower than the normal operating frequency of the system on the system on chip (SoC), and a plurality of pins configured on each of the transmitting die and the receiving die, wherein the plurality of pins are configured to communicate a design for test (DFT) vector at the test frequency.

All directional references (e.g., proximal, distal, upper, lower, upward, downward, left, right, lateral, longitudinal, front, back, top, bottom, above, below, vertical, horizontal, radial, axial, clockwise, and counterclockwise) are only used for identification purposes to aid the reader's understanding of the structures disclosed herein, and do not create limitations, particularly as to the position, orientation, or use of such structures. Connection references (e.g., attached, coupled, connected, and joined) are to be construed broadly and may include intermediate members between a collection of elements and relative movement between elements unless otherwise indicated. As such, connection references do not necessarily infer that two elements are directly connected and in fixed relation to each other. The example drawings are for purposes of illustration only and the dimensions, positions, order and relative sizes reflected in the drawings attached hereto may vary.

The above specification, examples and data provide a complete description of the structure and use of example embodiments of the invention as defined in the claims. Although various embodiments of the claimed invention have been described above with a certain degree of particularity, or with reference to one or more individual embodiments, other embodiments using different combinations of elements and structures disclosed herein are contemplated, as other iterations can be determined based upon the teachings of the present disclosure. It is intended that all matter contained in the above description and shown in the accompanying drawings shall be interpreted as illustrative only of particular embodiments and not limiting. Changes in detail or structure may be made without departing from the basic elements of the invention as defined in the following claims.

What is claimed is:

1. A device, comprising:
a transmitting die including a transmitter;
a receiving die including a receiver;
wherein the transmitting die and the receiving die are configured to be used on a system on chip (SoC);
an interposer configured to communicate between the transmitting die and the receiving die at a test frequency that is equal or lower than the normal operating frequency of the system on chip (SoC).

2. The device of claim 1, wherein each of the transmitting die and the receiving die includes a plurality of pins that are configured to communicate with the interposer at the test frequency.

3. The device of claim 1, wherein the test frequency is 400 MHz or less.

4. The device of claim 1, wherein the transmitting die and the receiving die are configured to be connected using a link macro, wherein the data connections of the transmitting die and the receiving die are single bumped and wherein the clock connections between the transmitting die and the receiving die are double bumped.

5. The device of claim 4, wherein the clock connections between the transmitting die and the receiving die are single bumped.

6. The device of claim 1, wherein the data communicated between the transmitting die and the receiving die includes redundancy such that n interposer routes are used to communicate m physical bits, wherein n is greater than m.

7. The device of claim 6, wherein n is three (3) and m is one (1).

8. The device of claim 1, wherein one input logic bit from the transmitting die is communicated as n physical bits over n interposer routes to the receiving die, wherein n being greater than one.

9. The device of claim 8, wherein the interposer route is configured to communicate at the test frequency.

10. The device of claim 8, wherein the receiving die is configured to have a majority vote logic to receive the n physical bits over n interposer routes and to convert the n physical bits to one output logic bit.

11. A die-to-die communication system, comprising:
a transmitter configured on a transmitting die;
a receiver configured on a receiving die;
an interposer configured to communicate between the transmitting die and the receiving die at a test frequency that is equal or lower than the normal operating frequency of the system on a system on chip (SoC); and
a plurality of pins configured on each of the transmitting die and the receiving die, wherein the plurality of pins are configured to communicate with the interposer at the test frequency.

12. The die-to-die communication system of claim 10, wherein the transmitting die and the receiving die are configured to be connected using a link macro, wherein the data connections of the transmitting die and the receiving die are single bumped and wherein the clock connections between the transmitting die and the receiving die are double bumped.

13. The die-to-die communication system of claim 10, wherein the data communicated between the transmitting die and the receiving die includes redundancy such that n interposer routes are used to communicate m physical bits, wherein n is greater than m.

14. The die-to-die communication system of claim 10, wherein one input logic bit from the transmitting die is communicated as n physical bits over n interposer routes to the transmitting die, wherein n being greater than one.

15. The die-to-die communication system of claim 14, wherein the interposer route is configured to communicate at the test frequency.

16. The die-to-die communication system of claim 14, wherein the receiving die is configured to have a majority vote logic to receive the n physical bits over n interposer routes and to convert the n physical bits to one output logic bit.

17. A system on chip, comprising:
a transmitting die;
a receiving die;
an interposer configured to communicate between the transmitting die and the receiving die at a test frequency that is at most one tenth of the normal operating frequency of the system on the system on chip (SoC); and
a plurality of pins configured on each of the transmitting die and the receiving die, wherein the plurality of pins are configured to communicate a design for test (DFT) vector at the test frequency.

18. The system on chip of claim 17, one input logic bit from the transmitting die is communicated as n physical bits over n interposer routes to the transmitting die, wherein n being greater than one and wherein the n physical bits are communicated at the test frequency.

19. The system on chip of claim 18, wherein the receiving die is configured to have a majority vote logic to receive the n physical bits over n interposer routes and to convert the n physical bits to one output logic bit.

20. The system on chip of claim 18, wherein the transmitting die and the receiving die are configured to be connected using a link macro, wherein the data connections of the transmitting die and the receiving die are single bumped and wherein the clock connections between the transmitting die and the receiving die are double bumped.
